(19) United States
(12) Patent Application Publication
(10) Pub. No.: US 2008/0211036 A1
(43) Pub. Date: Sep. 4, 2008

(54) Bipolar Resistive Memory Device Having Tunneling Layer

(75) Inventors: Jin Shi Zhao, Gyeonggi-do (KR); Jang-eun Lee, Gyeonggi-do (KR); In-gyu Baek, Seoul (KR); Se-chung Oh, Gyeonggi-do (KR); Kyung-tae Nam, Gyeonggi-do (KR); Eun-kyung Yim, Seoul (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 12/037,400

(22) Filed: Feb. 26, 2008

(30) Foreign Application Priority Data
Mar. 2, 2007 (KR) 2007-21170

(51) Int. Cl. H01L 29/8605; H01C 1/012

(52) U.S. Cl. 257/379; 338/309; 257/E29.326

(57) ABSTRACT

A nonvolatile memory device includes a semiconductor substrate, a first electrode on the semiconductor substrate, a resistive layer on the first electrode, a second electrode on the resistive layer and at least one tunneling layer interposed between the resistive layer and the first electrode and/or the second electrode. The resistive layer and the tunneling layer may support transition between first and second resistance states responsive to first and second voltages applied across the first and second electrodes. The first and second voltages may have opposite polarities.

### CROSS-REFERENCE TO RELATED PATENT APPLICATION

This application claims the benefit of Korean Patent Application No. 10-2007-0021170, filed on Mar. 2, 2007, in the Korean Intellectual Property Office, the disclosure of which is incorporated herein in its entirety by reference.

### FIELD OF THE INVENTION

The present invention relates to nonvolatile memory devices and, more particularly, to a resistor memory devices.

### BACKGROUND OF THE INVENTION

Memory devices include volatile memory devices, like DRAM (dynamic random access memory), in which if power is turned off, data stored in a memory cell is lost, and nonvolatile memory devices, in which data is maintained even after power is turned off. Nonvolatile memory devices include MRAM (magnetic random access memory), FRAM (ferroelectric random access memory), PRAM (phase-change random access memory), and RRAM (resistor random access memory). Volatile memory devices often have a capability for a high degree of integration and high operating speed. However, volatile memory typically has the disadvantage that, if power is turned off, stored data is lost. In contrast, nonvolatile memory devices typically retain data when the power is turned off, but may offer a lower degree of integration and a slow operating speed compared to DRAM or other types of volatile memory.

There have been ongoing efforts to improve integration, operating speed, power consumption and data retention of memory devices. Resistor memory devices are nonvolatile memory devices that may provide relatively less deterioration over multiple recording/reproducing operations compared to other nonvolatile memory devices and may also offer a superior level of data stability. Resistor memory devices may also offer high-speed operation, low power consumption and a capability for a high level of integration.

A typical resistor memory device includes a resistive layer interposed between an upper electrode and a lower electrode, and uses changing of the resistance state of the resistive layer according to the voltage applied to the electrodes to store data. FIG. 1 is a graph showing a change of the resistance of a resistive layer in a conventional resistor memory device with a unipolar operating characteristic. In FIG. 1, a curve “G1” is a voltage-current curve when the resistive layer is in a low resistance state, and a curve “G2” is a voltage-current curve when the resistive layer is in a high resistance state.

Referring to FIG. 1, if a voltage applied to the resistive layer is gradually increased, a current that flows through the resistive layer increases as the applied voltage increases. When the applied voltage increases above a first voltage V1, the resistance of the resistive layer abruptly increases, which causes the current to abruptly decrease. The high resistance state of the resistive layer is maintained until the applied voltage exceeds a second voltage V2. If the voltage applied to the resistive layer increases above the second voltage V2 to a third voltage V3, the resistance of the resistive layer abruptly decreases, causing an increase in the current.

Therefore, a current flowing through the resistive layer varies depending on the state of the resistance layer arising from a previously applied voltage. In other words, if the third voltage V3 is applied to the resistive layer so that the resistive layer is put into a low resistance “set” state and a voltage lower than the first voltage V1 is then applied to the resistive layer, current flows according to the curve G1. If, however, a voltage between the first voltage V1 and the second voltage V2 is applied to resistive layer so that the resistive layer is placed in a high resistance “reset” state and a voltage lower than the first voltage V1 is then applied to the resistive layer, a current flows according to the curve G2.

Therefore, the resistor memory device can program and read data using an electric characteristic in which a resistance of the resistive layer may be varied according to an applied voltage. For example, in programming data, data may be stored by designating the high resistance state of the resistive layer as a “0”, and by designating the low resistance state of the resistive layer as a “1”. In reading data, data is discriminated by applying a voltage lower than the first voltage V1 to the resistive layer and measuring a current flowing through the resistive layer. In other words, a “0” or “1” may be discriminated by determining whether the current flowing through the resistive layer follows the curve G1 or the curve G2.

In conventional resistive memory devices with a unipolar switching operating characteristic, a fatigue characteristic may be poor. This may lower the reliability of the device. Operating current may also be high, and operating speed may be limited.

### SUMMARY OF THE INVENTION

In some embodiments of the present invention, a nonvolatile memory device includes a semiconductor substrate, a first electrode on the semiconductor substrate, a resistive layer on the first electrode, a second electrode on the resistive layer and at least one tunneling layer interposed between the resistive layer and the first electrode and/or the second electrode. The resistive layer and the tunneling layer may support transition between first and second resistance states responsive to first and second voltages applied across the first and second electrodes. The first and second voltages may have opposite polarities.

In some embodiments, the resistive layer may include a transition metal oxide film and the tunneling layer may include a metal oxide film. For example, the resistive layer may include NiO, TiO₂, ZrO₂, HfO₂, WO₃, CoO or Nb₂O₅, and the tunneling layer may include MgO, AlOx or ZnO. In some embodiments, the resistive layer may have a thickness in a range from about 40 Å to about 1000 Å, more particularly, a thickness in a range from about 40 Å to about 100 Å. The tunneling layer may have a thickness in a range from about 1.0 Å to about 20 Å.

Further embodiments of the present invention provide a nonvolatile memory device including a semiconductor substrate, first and second impurity regions in the semiconductor substrate, a gate on the substrate between the first and second impurity regions and a storage element coupled to one of the first and second impurity regions. The storage element includes a first electrode connected to the one of the first and second impurity regions, a resistive layer on the first electrode, a second electrode on the resistive layer and at least one tunneling layer interposed between the resistive layer and the first electrode and/or the second electrode. The resistive layer and the tunneling layer may support transition between first and second resistance states responsive to first and second voltages applied across the first and second electrodes. The first and second voltages may have opposite polarities.

### BRIEF DESCRIPTION OF THE DRAWINGS

The above and other features and advantages of the present invention will become more apparent by describing in detail exemplary embodiments thereof with reference to the attached drawings in which:

FIG. 1 is a graph showing a voltage-current characteristic of a conventional unipolar resistive memory device;

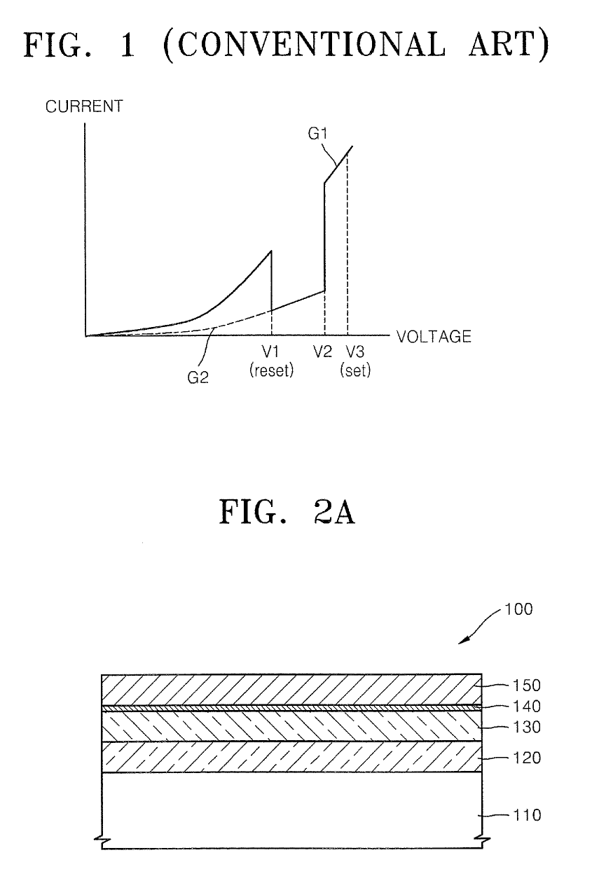

FIG. 2A-2C are cross-sectional views of bipolar resistor memory devices according to various embodiments of the present invention;

FIG. 3 illustrates an operating characteristic curve of the bipolar resistor memory device of FIGS. 2A-2C;

FIG. 4 is a graph showing a deterioration characteristic of the bipolar resistor memory device of FIGS. 2A-2C; and

FIG. 5A-5C are cross-sectional views of a nonvolatile memory cell utilizing a bipolar resistor memory device in a transistor structure according to some embodiments of the present invention.

### DETAILED DESCRIPTION OF EMBODIMENTS OF THE INVENTION

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art.

It will be understood that when an element or layer is referred to as being “on,” “connected to” and/or “coupled to” another element or layer, the element or layer may be directly on, connected and/or coupled to the other element or layer, or intervening elements or layers may be present. In contrast, when an element is referred to as being “directly on”, “directly connected to” and/or “directly coupled to” another element or layer, no intervening elements or layers are present. As used herein, the term “and/or” includes any and all combinations of one or more of the associated listed items.

It will also be understood that, although the terms “first,” “second,” etc., may be used herein to describe various elements, components, regions, layers and/or sections, these elements, components, regions, layers and/or sections should not be limited by these terms. Rather, these terms are used merely as a convenience to distinguish one element, component, region, layer and/or section from another element, component, region, layer and/or section. For example, a first element, component, region, layer and/or section could be termed a second element, component, region, layer and/or section without departing from the teachings of the present invention.

Spatially relative terms, such as “beneath,” “below,” “lower,” “above,” “upper,” “top,” “bottom” and the like, may be used to describe an element and/or feature's relationship to another element(s) and/or feature(s) as, for example, illustrated in the figures. It will be understood that the spatially relative terms are intended to encompass different orientations of the device in use and/or operation in addition to the orientation depicted in the figures. For example, when the device in the figures is turned over, elements described as below and/or beneath other elements or features would then be oriented above the other dements or features. The device may be otherwise oriented (rotated 90 degrees or at other orientations) and the spatially relative descriptors used herein interpreted accordingly. As used herein, “height” refers to a direction that is generally orthogonal to the faces of a substrate.

The terminology used herein is for the purpose of describing particular embodiments only and is not intended to limit of the invention. As used herein, the singular terms “a,” “an” and “the” are intended to include the plural forms as well, unless the context clearly indicates otherwise. It will be further understood that the terms “comprise,” “comprising,” “includes,” “including,” “have”, “having” and variants thereof specify the presence of stated features, integers, steps, operations, elements, and/or components, but do not preclude the presence and/or addition of one or more other features, integers, steps, operations, elements, components, and/or groups thereof.

Embodiments of the present invention may be described with reference to cross-sectional illustrations, which are schematic illustrations of idealized embodiments of the present invention. As such, variations from the shapes of the illustrations, as a result, for example, of manufacturing techniques and/or tolerances, are to be expected. Thus, embodiments of the present invention should not be construed as limited to the particular shapes of regions illustrated herein, but are to include deviations in shapes that result from, e.g., manufacturing. For example, a region illustrated as a rectangle may have rounded or curved features. Thus, the regions illustrated in the figures are schematic in nature and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of this specification and the relevant art and will not be interpreted in an idealized or overly formal sense unless expressly so defined herein.

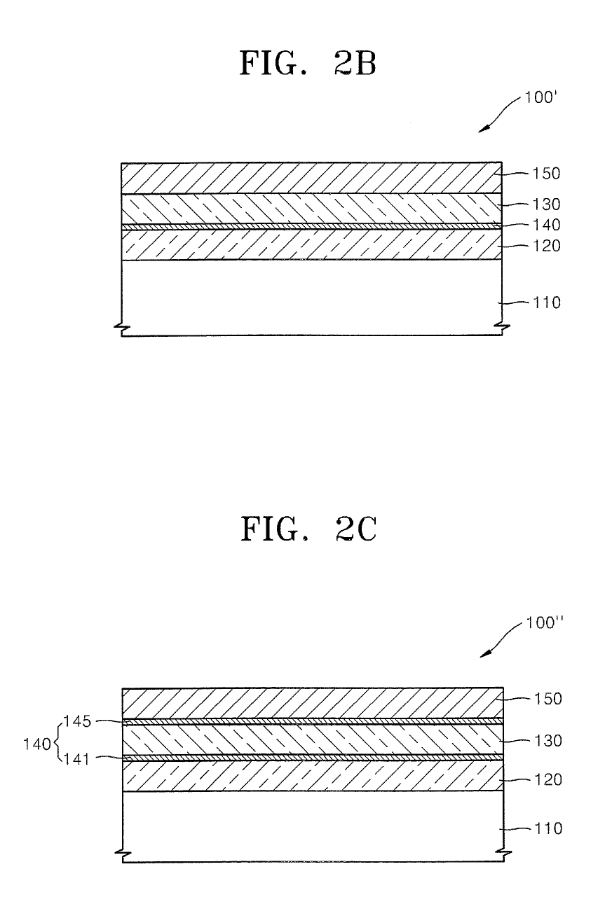

FIG. 2A-2C are cross-sectional views of resistor memory devices according to some embodiments of the present invention. Referring to FIGS. 2A-2C, each of resistor memory devices 100, 100′, 100″ includes a semiconductor substrate 110, a lower electrode 120 formed on the semiconductor substrate 110, and an upper electrode 150. The lower electrode 120 and the upper electrode 150 may be formed, for example, from conductive materials used in conventional semiconductor devices. For example, the lower electrode 120 and the upper electrode 150 may be metal electrodes, e.g., electrodes made from a noble metal, such as Ir, Pt or Ru. In some embodiments, the lower electrode 120 and the upper electrode 150 may comprise a conductive oxide, such as IrOx, RuOx or SrRuO₃. The lower electrode 120 may be selected, for example, depending on a material layer formed on its upper surface.

In each of the devices 100, 100′, 100″, a resistive layer 130 is interposed between the lower electrode 120 and the upper electrode 150. The resistive layer 130 may have a thickness in a range of 40-1000 Å, for example, a thickness in a range of 40-100 Å. The resistive layer 130 may be, for example, a monocrystalline film, an amorphous film or a polycrystalline film. The resistive layer 130 may comprise a transition metal oxide, such as NiO, TiO₂, HfO, ZrO, WO₃, CoO or Nb₂O₅.

In the device 100 of FIG. 2A, a thin film tunneling layer 140 is interposed between the resistive layer 130 and the upper electrode 150. The tunneling layer 140 may have a thickness less than that of the resistive layer 130, for example, a thickness in a range from about 1.0 Å to about 20 Å. The tunneling layer 140 may be, for example, a monocrystalline film, an amorphous film or a polycrystalline film. The tunneling layer 140 may comprise a material different from the resistive layer 130. In some embodiments, the tunneling layer 140 may comprise a metal oxide, such as MgO, AlOx or ZnO. The tunneling layer 140, in conjunction with the resistive layer 130, may vary resistance of the device 100 according to a voltage applied across the upper and lower electrodes 150, 120. In this manner, the device 100 may transition between a high-resistance state and a lower-resistance state.

In the device 100′ of FIG. 2B, a tunneling layer 140 may be interposed between the lower electrode 120 and the resistive layer 130. In the device 100″, multiple tunneling layers 140 may be interposed between the upper electrode 150 and the resistive layer 130 and between the lower electrode 120 and the resistive layer 130. The tunneling layer 140 may comprise a first tunneling layer 141, which is interposed between the lower electrode 120 and the resistive layer 130 and a second tunneling layer 145, which is interposed between the resistive layer 130 and the upper electrode 150.

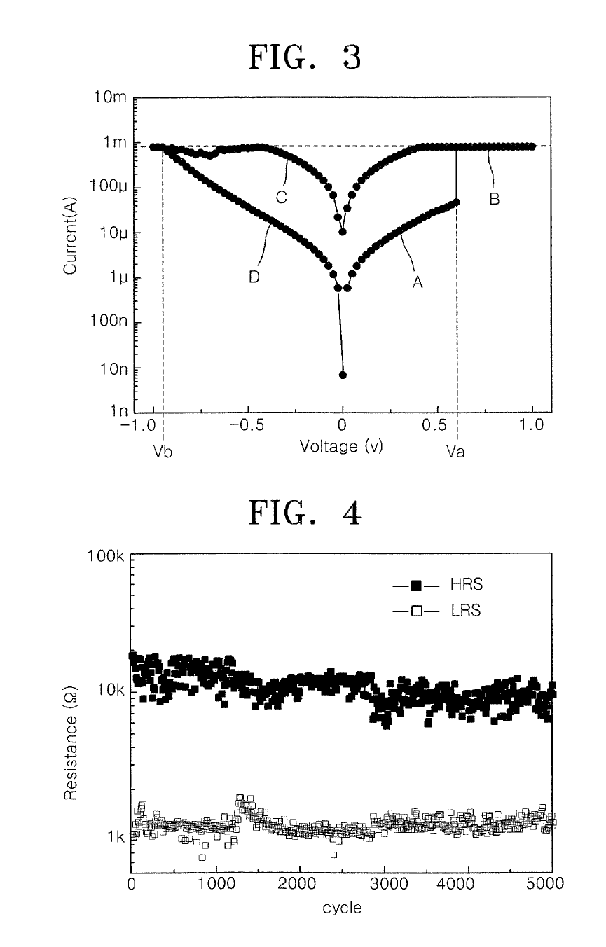

Operations of a device along the lines described above with reference to FIGS. 2A-2C will now be described with reference to FIG. 3. If a positive voltage applied across the electrodes 150, 120 is less than a predetermined voltage Va, the device 100, 100′, 100″ maintains a high resistance state A. If a higher voltage than the predetermined voltage Va is applied, a soft breakdown phenomenon occurs in the resistive layer 130 so that a filament is formed therein. A high current may flow through the filament to an interface between the resistive layer 130 and the tunneling layer 140, which may cause formation of a pinhole or a tunnel through the tunneling layer 140. This may cause a transition of the device to a low resistance state at a point B due to current flow through the filament via the pinhole or tunnel. This low resistance state may be referred to as a “forming” state or a “set”. After transitioning to the low resistance state, the device maintains the low resistance state, which results in a higher current for a given voltage across the electrodes 150, 120.

If a negative voltage of a magnitude less than a predetermined negative voltage Vb is applied after transitioning to the low resistance set state, the device 100, 100′, 100″ maintains a low resistance state at point C. If the applied voltage becomes more negative than the predetermined negative voltage Vb, however, an oxidation or reduction reaction may occur due to moving of oxygen atom or oxygen ion, which may cause the pin hole to disappear and/or the connection to the filament at the interface between the resistive layer 130 and the tunneling layer 140 to be broken. This may cause the device to transition back to the high resistance “reset” state at point D.

Accordingly, in the resistor memory devices 100, 100′, 100″, data may be programmed and read using such different resistive states. For example, in programming data, a “1” may be stored by transitioning the device 100, 100′, 100″ to the low resistance state by applying a voltage greater than the predetermined positive voltage Va. A “0” state may be programmed by applying a negative voltage that is less (more negative) then the predetermined negative voltage Vb to transition the device 100, 100′, 100″ to a high resistance state.

In a read operation, data is discriminated by applying a predetermined voltage to the device 100, 100′, 100″ to measure a current flowing through the device 100, 100′, 100″. In particular, a voltage less than the predetermined positive voltage Va and greater than the predetermined negative voltage Vb may be applied to the device 100, 100′, 100″ and the resulting current measured. “0” or “1” may be discriminated according to whether measured current corresponds to the low resistance state or the high resistance state.

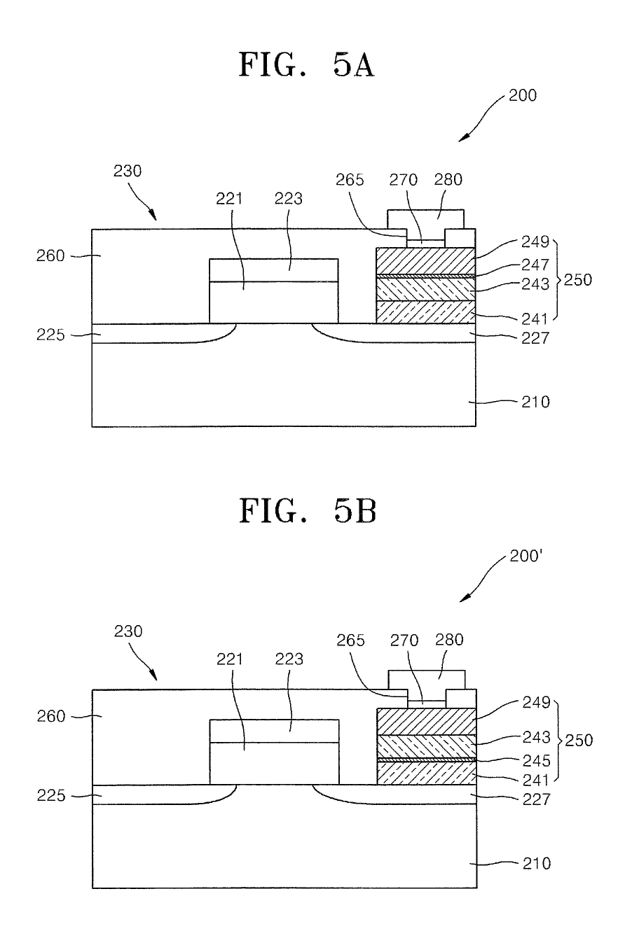

FIG. 4 shows a fatigue characteristic of a resistor memory device along the lines of the resistor memory devices 100, 100′, 100″ illustrated in FIGS. 2A-2C. In FIG. 4, HRS indicates when the resistive layer 130 is in a high resistance reset state, and LRS indicates when the device is in a low resistance set state. In the figure, switching of the device from the high resistance state to the low resistance state or from the low resistance state to the high resistance state constitutes a cycle. The resistance when the device is in the high resistance state is more than about 10 times the resistance of the device when in the low resistance state. As shown, over 5000 cycles, the resistance difference between the high resistance state and the low resistance state remains relatively stable.

The resistor memory devices 100, 100′, 100″ have bipolar switching operating characteristics due to use of a tunneling layer 140 between the resistive layer 130 and the lower electrode 120 and/or the upper electrode 150. Because these devices may have a low operating voltage and a low current, the number of switching can be increased and a stable operation margin may be provided. In addition, since the deterioration of the resistive layer 130 by a pulse type of voltage applied the resistive layer 130 may be reduced, reliability and endurance and data retention characteristic may be improved.

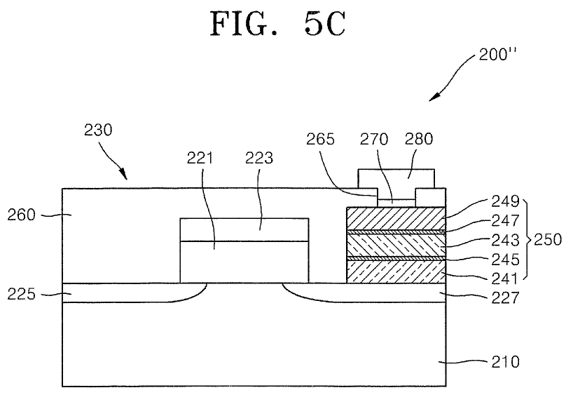

FIG. 5A through FIG. 5C are cross-sectional views of a nonvolatile memory devices using the resistor memory devices shown in FIG. 2A-2C in a transistor structure. Referring to FIGS. 5A-5C, each nonvolatile memory device 200, 200′, 200″ includes a semiconductor substrate 210, a transistor 230 and a storage element 250. The transistor 230 includes a gate insulation film 221 formed on the semiconductor substrate 210, a gate 223 formed on the gate insulation film 221, and a source and drain regions 225 and 227 formed in the substrate 210 on respective sides of the gate 223. The source and drain regions 225 and 227 may be, for example, impurity regions having a conductivity type opposite to that of the substrate 210.

A storage element 250 is formed on the semiconductor substrate 210 so as to be in contact with one of the source and drain regions 225, 227, in particular, the drain region 227. A lower electrode 241 is formed on the semiconductor substrate 210 in contact with the drain region 227, and a resistive layer 243 is formed on the lower electrode 241. An upper electrode 249 is formed on the resistive layer 243. In the device 200, a tunneling layer 245 is interposed between the resistive layer 243 and the upper electrode 249. A resistance value of the storage element 250 may be changed responsive to a voltage applied thereto. In the device 200′, a tunneling layer 245 is interposed between the lower electrode 241 and the resistive layer 243. In the device 200″, a first tunneling layer 245 is interposed between the lower electrode 241 and the resistive layer 243, and a second tunneling layer 247 is interposed between the resistive layer 243 and the upper electrode 249.

The tunneling layers 245, 247 comprise a material different from the resistive layer 243, and have a thickness less than that of the resistive layer 243. For example, the resistive layer 243 may have a thickness in a range from about 40 Å to about 1000 Å, for example, a thickness in a range from about 40 Å to about 100 Å. The resistive layer 243 may comprise a transition metal oxide film, for example NiO, TiO₂, ZrO₂, HfO₂, WO₃, CoO or Nb₂O₅. The tunneling layer 245 and 247 may have a thickness in a range from about 1.0 Å to about 20 Å. The tunneling layer may comprise a metal oxide film, for example MgO, AlOx or ZnO.

An interlayer insulation film 260 may be formed on the semiconductor substrate 210, covering the transistor 230 and the storage element 250. The interlayer insulation film 260 may include a hole 265 that exposes the upper electrode 249 of the storage element 250. A plate 280, which is connected to the upper electrode 249 via the hole 265, may be further formed. The plate 280 may comprise, for example, aluminum (Al). A barrier metal 270 may be further formed between the plate 280 and the upper electrode 249.

In the illustrated embodiments, the lower electrode 241 of the memory device 250 is formed directly in contact with the drain region 227. In other embodiments, however, an interlayer insulation film (not shown) may be formed on the semiconductor substrate 210 and the storage element 250 formed thereon, and the lower electrode 241 of the storage element 250 may be connected through a hole in the interlayer insulation film to the drain region 227.

As described in detail above, nonvolatile resistor memory devices may be provided with a bipolar characteristic by interposing a tunneling layer between a resistive layer and an electrode. Accordingly, operating characteristics, endurance and data retention of such a device may be thus improved. In addition, nonvolatile memory devices according to some embodiments of the present invention may enjoy a low operating voltage and current, which may improve the deterioration characteristic of the resistive layer, such that the reliability of the memory devices may be improved.

While the present invention has been particularly shown and described with reference to exemplary embodiments thereof, it will be understood by those of ordinary skill in the art that the present invention is not limited thereto, and various changes in form and details may be made therein without departing from the spirit and scope of the present invention as defined by the following claims.

What is claimed is:

1. A nonvolatile memory device, comprising:
a semiconductor substrate;
a first electrode on the semiconductor substrate;
a resistive layer on the first electrode;
a second electrode on the resistive layer; and
at least one tunneling layer interposed between the resistive layer and the first electrode and/or the second electrode.

2. The nonvolatile memory device of claim 1, wherein the resistive layer and the tunneling layer support transition between first and second resistance states responsive to first and second voltages applied across the first and second electrodes.

3. The nonvolatile memory device of claim 2, wherein the first and second voltages have opposite polarities.

4. The nonvolatile memory device of claim 1, wherein the at least one tunneling layer is thinner than the resistive layer.

5. The nonvolatile memory device of claim 1, wherein the resistive layer comprises an amorphous film, a monocrystalline film or a polycrystalline film.

6. The nonvolatile memory device of claim 1, wherein the resistive layer comprises a transition metal oxide film, and wherein the tunneling layer comprises a metal oxide film.

7. The nonvolatile memory device of claim 6, wherein the resistive layer comprises NiO, TiO₂, ZrO₂, HfO₂, WO₃, CoO or Nb₂O₅.

8. The nonvolatile memory device of claim 6, wherein the tunneling layer comprises MgO, AlOx or ZnO.

9. The nonvolatile memory device of claim 6, wherein the resistive layer has a thickness in a range from about 40 Å to about 1000 Å.

10. The nonvolatile memory device of claim 9, wherein the resistive layer has a thickness in a range from about 40 Å to about 100 Å.

11. The nonvolatile memory device of claim 6, wherein the tunneling layer has a thickness in a range from about 1.0 Å to about 20 Å.

12. The nonvolatile memory device of claim 1, wherein the tunneling layer comprises a material different from the resistive layer.

13. The nonvolatile memory device of claim 1, wherein the tunneling layer comprises a polycrystalline film, a monocrystalline firm or an amorphous film.

14. A nonvolatile memory device, comprising:
a semiconductor substrate;
first and second impurity regions formed in the semiconductor substrate;
a gate on the substrate between the first and second impurity regions; and
a storage element coupled to one of the first and second impurity regions, the storage element comprising:
a first electrode connected to the one of the first and second impurity regions;
a resistive layer on the first electrode;
a second electrode on the resistive layer; and
at least one tunneling layer interposed between the resistive layer and the first electrode and/or the second electrode.

15. The nonvolatile memory device of claim 14, wherein the resistive layer and the tunneling layer support transition between first and second resistance states responsive to first and second voltages applied across the first and second electrodes.

16. The nonvolatile memory device of claim 17, wherein the first and second voltages have opposite polarities.

17. The nonvolatile memory device of claim 14, wherein the tunneling layer is thinner than the resistive layer.

18. The nonvolatile memory device of claim 14, wherein the resistive layer comprises a transition metal oxide film and wherein the tunneling layer comprises a metal oxide film.

19. The nonvolatile memory device of claim 18, wherein the resistive layer comprises NiO, TiO₂, ZrO₂, HfO₂, WO₃, CoO or Nb₂O₅ and wherein the tunneling layer comprises MgO, AlOx or ZnO.

20. The nonvolatile memory device of claim 18, wherein the resistive layer has a thickness in a range from about 40 Å to about 1000 Å and wherein the tunneling layer has a thickness in a range from about 1.0 Å to about 20 Å.
